(19) United States
(12) Patent Application Publication
(10) Pub. No.: US 2012/0115326 A1
(43) Pub. Date: May 10, 2012

(54) Method of Forming Metal Silicide Regions

(75) Inventors: Kai Frohberg, Niederau (DE); Jens Heinrich, Wachau (DE); Katrin Reiche, Goltzscha (DE)

(73) Assignee: GLOBALFOUNDRIES INC., Grand Cayman (KY)

(21) Appl. No.: 12/942,116

(22) Filed: Nov. 9, 2010

(51) Int. Cl. H01L 21/321

(52) U.S. Cl. 438/664; 257/E21.296

(57) ABSTRACT

The method described herein involves the formation of metal silicide regions. The method may involve forming a layer of refractory metal on a structure comprising silicon, forming a layer of silicon on the layer of refractory metal and, after forming the layer of silicon, performing at least one heat treatment process to form a metal silicide region in the structure.

### BACKGROUND OF THE INVENTION

1. Field of the Invention

The present disclosure is generally directed to the field of semiconductor processing, and, more particularly, to a method of forming metal silicide regions on a semiconductor device.

2. Description of the Related Art

There is a constant drive within the semiconductor industry to increase the operating speed of integrated circuit devices, e.g., microprocessors, memory devices, etc. This drive is fueled by consumer demands for computers and electronic devices that operate at increasingly greater speeds. This demand for increased speed has resulted in a continual reduction in the size of semiconductor devices, e.g., transistors. That is, the size of many components of a typical field effect transistor, e.g., channel length, source/drain junction depths, gate dielectric thickness, etc., are reduced. For example, all other things being equal, the smaller the channel length of the transistor, the faster the transistor will operate. Thus, there is a constant drive to reduce the size, or scale, of the components of a typical transistor to increase the overall speed of the transistor, as well as integrated circuit devices incorporating such transistors. However, the reduction in the channel length also requires a reduction in the depth of the source and drain regions adjacent the gate conductor.

One operation that is typically performed on traditional semiconductor devices is the formation of metal silicide regions. In general, the formation of metal silicide regions involves forming a layer of refractory metal, e.g., cobalt, titanium, nickel, platinum or tungsten, above a gate conductor and/or the source/drain regions of a transistor device, and, thereafter, subjecting the device to one or more heat treatment processes such that a metal silicide, e.g., cobalt silicide, titanium silicide, nickel silicide, platinum silicide or tungsten silicide, is formed where the refractory metal is exposed to silicon. The purpose of the metal silicide regions is to, among other things, reduce the electrical resistance of the components where such regions are located, thereby increasing the operating speed of the device.

One illustrative process flow for forming an illustrative NMOS transistor 10 having such metal silicide contacts will now be described with reference to FIGS. 1A-1C. As shown in FIG. 1A, a semiconducting substrate 11 has shallow trench isolation regions 14 formed therein to thereby define an active area 15 of the substrate 11. A gate insulation layer 16, e.g., silicon dioxide, and a gate electrode 18, e.g., polysilicon, are formed above a surface 12 of the substrate 11 by forming the appropriate layers of material and then performing one or more known masking and etching processes to pattern the layers. Thereafter, extension implant regions 20 are formed in the substrate 11 by performing an ion implantation process. Note that during this process, the extension implant regions 20 are generally self-aligned with respect to sidewalls 18A of the gate electrode 18. For PMOS devices, a relatively small sidewall spacer (not shown) may be formed adjacent the gate electrode 18 prior to the extension implant process to compensate for increased mobility of some dopant atoms that may be implanted in PMOS devices, e.g., boron. In present day devices, the channel length of transistors may be on the order of 200-300 nm or less, and further reductions are likely in the future.

Thereafter, as indicated in FIG. 1B, a sidewall spacer 22 is formed adjacent the gate electrode 18. The sidewall spacer 22 may be formed by depositing an appropriate layer(s) of spacer material followed by performing an anisotropic etching process. The width of the spacer 22 at the point where the spacer 22 intersects the surface 12 of the substrate 10 may vary depending upon the application, e.g., it may have a width that ranges from approximately 20-150 nm. After the formation of the spacer 22, a source/drain implant process is performed to form source/drain implant regions 24. Note that during this process, the source/drain implant regions 24 are generally self-aligned with respect to the sidewall spacer 22. In general, the source/drain implant regions 24 are deeper and have a higher concentration of dopant atoms as compared to the extension implant regions 20. Due to the relatively high concentration of dopant atoms used during the source/drain implant process, only the portion of the extension implant region 20 protected by the sidewall spacer 22 continues to have a relatively light concentration of dopant atoms. This area is generally referred to as source/drain extensions 20A of the transistor 10. Note that, in FIG. 1B, the various implant regions are schematically depicted in their implanted positions. After one or more heating processes are performed on the device, the implanted dopant atoms will move or migrate from the implanted positions to the approximate positions indicated in FIG. 1C.

Next, metal silicide regions 28 are formed on the source/drain regions and the gate electrode 18. The thickness of the metal silicide regions 28 may vary depending upon the particular application. In one illustrative embodiment, the metal silicide regions 28 may have a thickness on the order of approximately 8-30 nm. The metal silicide regions 28 may be formed by depositing a layer (not shown) comprised of approximately 4-15 nm of an appropriate refractory material, e.g., cobalt, titanium, nickel, platinum, tungsten, etc., and thereafter performing one or more heating processes to convert the portions of the refractory metal layer in contact with a silicon surface into a metal silicide, e.g., cobalt silicide, titanium silicide, etc. The portions of the refractory metal layer that are in contact with non-silicon surfaces, e.g., sidewall spacer 22, the isolation regions 14 and the like, are not converted to a metal silicide, and they may be subsequently removed by chemical etch (wet) processes.

However, there are problems associated with forming metal silicide regions 28 using such traditional techniques as that described above. For example, in some cases, if non-optimal process conditions are used, some of the refractory metal, e.g., nickel, will not be converted to a metal silicide, i.e., it remains as unconverted nickel. During the subsequent wet etch cleaning process, the unreacted metal may be removed, thereby resulting in pits or holes in the metal silicide region. Ultimately, such holes in the metal silicide region can result in problems such as contact etch punchthrough and ultimately electrical shorts in the finished device.

The present invention is directed to solving, or at least reducing, some or all of the aforementioned problems.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

A novel transistor device and method of making same is disclosed herein. In one illustrative embodiment, the method comprises forming a metal silicide region by forming a layer of refractory metal on a structure comprising silicon, forming a layer of silicon on the layer of refractory metal and, after forming the layer of silicon, performing at least one heat treatment process to form a metal silicide region in the structure.

In another illustrative embodiment, the method comprises forming a metal silicide region by depositing a layer of refractory metal on at least a plurality of regions formed in a silicon-containing substrate, depositing a layer of silicon on the layer of refractory metal, after depositing the layer of silicon, performing at least one heat treatment process on the silicon-containing substrate, the layer of refractory metal and the layer of silicon to form a metal silicide region in the structure, and performing a wet etching process after performing the at least one heat treatment process to remove unreacted portions of the layer of refractory metal.

### BRIEF DESCRIPTION OF THE DRAWINGS

The disclosure may be understood by reference to the following description taken in conjunction with the accompanying drawings, in which like reference numerals identify like elements, and in which:

FIGS. 1A-1C depict one illustrative prior art process flow for forming metal silicide contacts on a semiconductor device; and

FIGS. 2A-2C depict one illustrative embodiment of the subject matter disclosed herein.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the present subject matter are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

In general, the present disclosure is directed to forming metal silicide regions on a silicon-containing structure, such as a semiconductor device, and a device incorporating such regions. As will be readily apparent to those skilled in the art upon a complete reading of the present application, the present method is applicable to a variety of technologies, e.g., NMOS, PMOS, CMOS, etc., and is readily applicable to a variety of devices, including, but not limited to, logic devices, memory devices, resistors, conductive lines, etc.

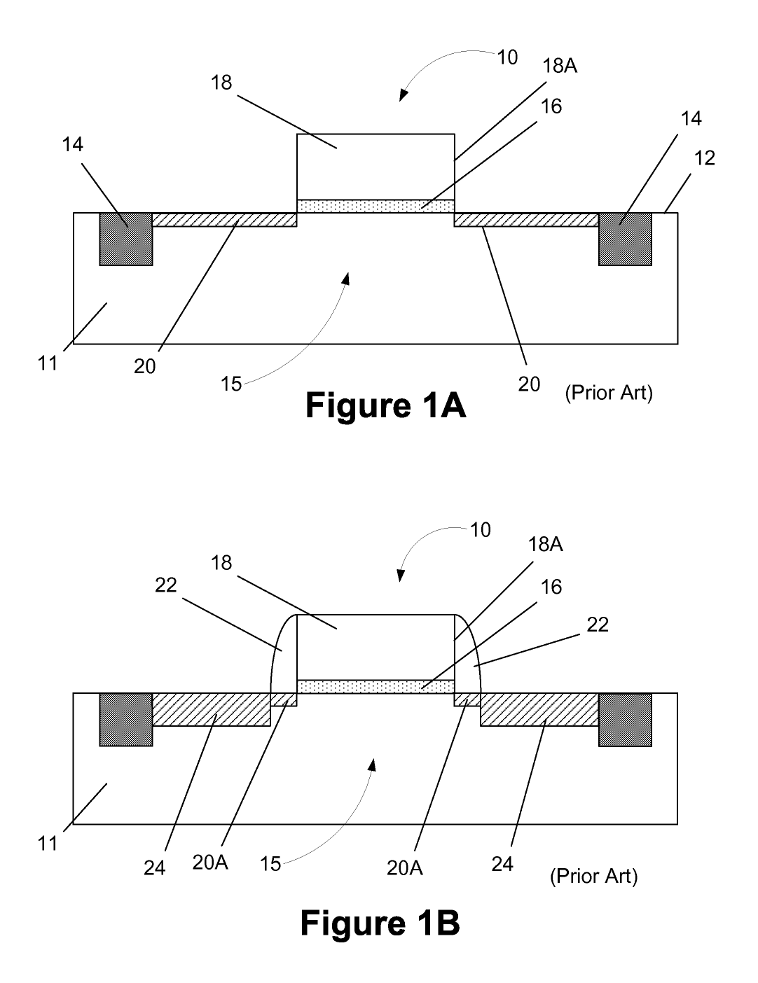

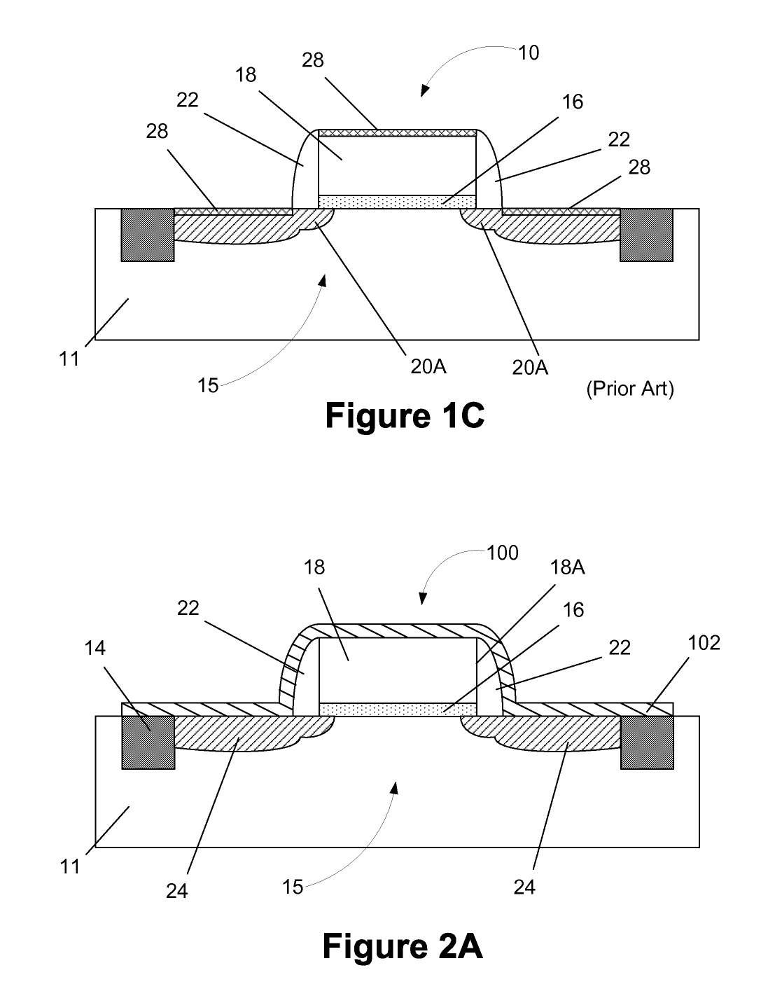

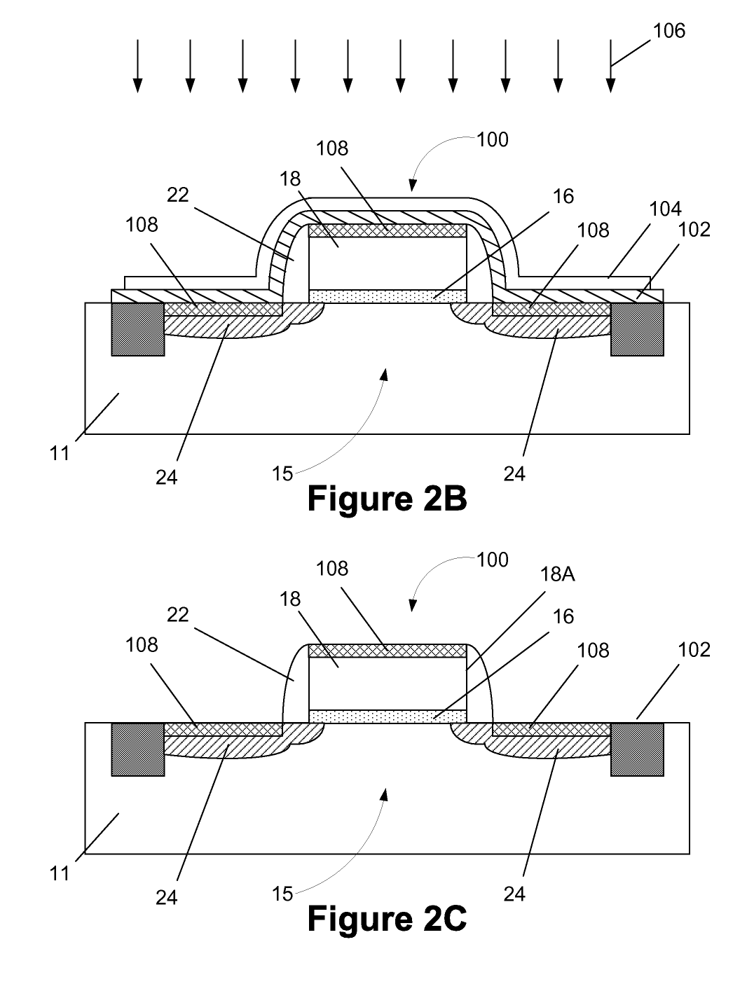

FIG. 2A depicts an illustrative transistor 100 at a point in the fabrication process that is essentially the same as that depicted in FIG. 1C prior to the formation of the metal silicide regions 28 depicted in FIG. 1C. To the extent the reference numbers are the same, the description of the structures and components of the transistor 100 are the same as previously described with reference to FIGS. 1A-1C. As shown in FIG. 2A, a partially formed transistor 100 is formed in and above a surface of a semiconducting substrate 11. In one illustrative embodiment, the semiconducting substrate 11 is comprised of silicon. In the embodiments depicted herein, the substrate 11 is depicted in a bulk configuration. However, the present invention is equally applicable to other configurations, such as a silicon-on-insulator (SOI) type structures. Thus, the terms substrate or semiconductor substrate should be understood to cover all semiconductor structures. Shallow trench isolation regions 14 are formed in the substrate 11 to thereby define an active area 15 where the transistor 100 will be formed. At the stage of manufacture depicted in FIG. 2A, the transistor 100 is comprised of a gate insulation layer 16, a gate electrode 18, a sidewall spacer 22, and source/drain regions 24.

The illustrative transistor 100 may be formed using a variety of known techniques and materials. For example, the gate insulation layer 16 may be comprised of a variety of materials, e.g., a metal oxide, metal silicate, silicon dioxide, silicon nitride, an oxynitride, a silicon nitride/silicon dioxide bilayer, etc., and it may be formed by a variety of techniques, e.g., chemical vapor deposition (CVD), low pressure chemical vapor deposition (LPCVD), thermal growth, etc. In one illustrative embodiment, the gate insulation layer 16 is comprised of a thermally grown layer of silicon dioxide having a thickness ranging from approximately 0.002-0.005 nm. Similarly, the gate electrode 18 may be comprised of a variety of materials, e.g., polysilicon, etc. As will be recognized by those skilled in the art, the gate insulation layer 16 and the gate electrode 18 depicted in FIG. 2A may be formed by forming the appropriate layers of material and thereafter, using traditional photolithography and etching techniques, patterning the layers to result in the structures depicted in FIG. 2A.

The sidewall spacer 22 may be formed by forming an appropriate layer(s) (not shown) of material above the surface of the substrate 11 and thereafter performing an anisotropic etching process to define the sidewall spacer 22 positioned adjacent the sidewall 18A of the gate electrode 18. The sidewall spacer 22 may be comprised of a variety of materials, e.g., silicon dioxide, silicon oxynitride, silicon nitride, an oxide, an oxynitride, etc. Moreover, the layer from which the sidewall spacer 22 may be formed can be manufactured using a variety of techniques, e.g., CVD, LPCVD, etc. In one illustrative embodiment, the thickness of the sidewall spacer 22 at is base may range from approximately 20-150 nm.

Pursuant to the present disclosure, a layer of refractory metal 102 is formed on the partially formed transistor 100, including the gate electrode 18 and the source/drain regions 24. The layer of refractory metal 102 may be comprised of, for example, nickel, cobalt, titanium, platinum, etc., and it may have a thickness that varies depending on the particular application. For example, the layer of refractory metal may have a thickness that ranges from approximately 1-15 nm. The layer of refractory metal 102 may be formed by any of a variety of known techniques, e.g., CVD, PVD, PECVD, etc.

As shown in FIG. 2B, a layer of silicon 104 is then formed on the layer of refractory metal 102. The thickness of the layer of silicon 104 may vary depending upon the particular application. For example, in one illustrative embodiment, the layer of silicon 104 may have a thickness ranging from approximately 1-5 nm. The layer of silicon 104 may be formed using a variety of known techniques, e.g., CVD, PVD, PECVD, etc.

After the layer of silicon 104 is formed, one or more heating processes 106 are performed to initiate a reaction between the layer of refractory metal 102 and the silicon in the layer of silicon 104, the source/drain regions 24 and the gate electrode 18 to thereby form metal silicide regions 108. In one illustrative embodiment, metal silicide regions 108 may have a thickness ranging from 5-20 nm depending on the particular application. Of course, if desired, the metal silicide regions 108 may be selectively formed on various structures, e.g., such as the source/drain regions 24, if desired, by the use of appropriate masking layers.

In one illustrative example, the heating process 106 may be a two-step heating process. For example, the heating process 106 may comprise a first heating step at a temperature that may range from approximately 450-550° C. to produce a monosilicide, e.g., cobalt monosilicide. Thereafter, one or more chemical etching processes may be performed to remove unreacted portions of the refractory metal layer 102 and the layer of silicon 104. Next, a second heating step may be performed at a higher temperature of approximately 700° C. or higher to convert the monosilicide into disilicide, e.g., to convert cobalt monosilicide to cobalt disilicide. Alternatively, the heat treatment process 106 may be performed at various temperatures for various durations until such time as the metal silicide regions 108 are substantially completely formed prior to performing any wet chemical cleaning process. In one illustrative embodiment, the layer of silicon 104 may be substantially consumed in the area above the source/drain regions 24 and the gate electrode 18 during the formation of the metal silicide regions 108.

In one illustrative embodiment, the method described herein comprises forming a layer of refractory metal 102 on a structure comprising silicon, such as the gate electrode 18 and/or the source/drain regions 24, forming a layer of silicon 104 on the layer of refractory metal 102 and, after forming the layer of silicon 104, performing at least one heat treatment process to form a metal silicide region 108 in the silicon-containing structure.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention.

Accordingly, the protection sought herein is as set forth in the claims below.

What is claimed:

1. A method of forming a metal silicide region, comprising:
forming a layer of refractory metal on a structure comprising silicon;
forming a layer of silicon on said layer of refractory metal; and
after forming said layer of silicon, performing at least one heat treatment process to form a metal silicide region in said structure.

2. The method of claim 1, further comprising performing a wet etching process after performing said at least one heat treatment process.

3. The method of claim 1, wherein said layer of refractory metal comprises at least one of nickel, cobalt, titanium, platinum and tungsten.

4. The method of claim 3, wherein said layer of refractory metal has a thickness ranging from 1-15 nm.

5. The method of claim 1, wherein said layer of silicon has a thickness ranging from 1-5 nm.

6. The method of claim 1, wherein said structure comprises at least one of a gate electrode structure, a source/drain region, a resistor and a conductive line.

7. The method of claim 1, wherein performing said at least one heat treatment process comprises performing a first heating step at a temperature of 450-550° C. and performing a second heating step at a temperature of at least 700° C.

8. The method of claim 7, further comprising performing at least one wet chemical cleaning process after performing said first heating step but prior to performing said second heating step.

9. The method of claim 1, wherein, in performing said at least one heat treatment process, said metal silicide region is formed using said structure and said layer of silicon as a source of silicon during the formation of said metal silicide region.

10. A method of forming a metal silicide region, comprising:
depositing a layer of refractory metal on a structure comprising silicon;
depositing a layer of silicon on said layer of refractory metal; and
after depositing said layer of silicon, performing at least one heat treatment process to form a metal silicide region in said structure, wherein said structure and said layer of silicon are used as sources of silicon during the formation of said metal silicide region.

11. The method of claim 10, further comprising performing a wet etching process after performing said at least one heat treatment process.

12. The method of claim 10, wherein said layer of refractory metal comprises at least one of nickel, cobalt, titanium, platinum and tungsten.

13. The method of claim 10, wherein said structure is a gate electrode structure and a source region and a drain region of a transistor.

14. A method of forming a metal silicide region, comprising:
depositing a layer of refractory metal on at least a plurality of regions formed in a silicon-containing substrate;
depositing a layer of silicon on said layer of refractory metal;
after depositing said layer of silicon, performing at least one heat treatment process on said silicon-containing substrate, said layer of refractory metal and said layer of silicon to form a metal silicide region in said structure; and
performing a wet etching process after performing said at least one heat treatment process to remove unreacted portions of said layer of refractory metal.

15. The method of claim 14, wherein said plurality of regions are source/drain regions.

16. The method of claim 14, wherein said layer of refractory metal is deposited on a silicon-containing structure formed above said substrate.

17. The method of claim 16, wherein said silicon-containing structure comprises at least one of a gate electrode and a resistor.
